(19) United States
(12) Patent Application Publication
(10) Pub. No.: US 2001/0037993 A1
(43) Pub. Date: Nov. 8, 2001

(54) Etching method and wiring board manufactured by the method

(76) Inventor: Katsuo Iwasaki, Ishikawa (JP)

Correspondence Address: Ratner & Prestia, P.O. Box 980, Valley Forge, PA, 19482, US

(21) Appl. No.: 09/903,165

(22) Filed: Jul. 11, 2001

Related U.S. Application Data
(62) Division of application No. 09/158,567, filed on Sep. 22, 1998.

(30) Foreign Application Priority Data
Sep. 22, 1997 (JP) 9-256609

(51) Int. Cl. H01B 13/00; H05K 1/00; C23F 1/02

(52) U.S. Cl. 216/13; 156/345; 174/250

(57) ABSTRACT

A wet etching apparatus for finely processing a metal thin film of aluminum or mainly composed of aluminum has an ion chromatograph for automatically measuring the concentration of etching substances contained in an etchant, a calculating device for calculating the addition amounts according to the results of measurement, and an adding device for supplying desired amounts of etching substances into the tank depending on the results of calculation. Accordingly, the composition of the etchant containing water and etching substances such as phosphoric acid, nitric acid and acetic acid can be controlled within a desired concentration range. During the etching process, by controlling the concentration of the etching substances contained in the etchant, the etching shape of the metal thin film and the etching speed can be controlled and stabilized. The wiring board thus obtained can be used as the gate wiring and source wiring used in the array substrate of a liquid crystal display, and a liquid crystal display having a stable display is obtained.

### FIELD OF THE INVENTION

The present invention relates to an apparatus for etching a metal thin film, a wiring board manufactured by using this apparatus, and a manufacturing method of such wiring board. More particularly, in a wet etching method for processing the section of a metal thin film in a taper shape of a specific angle, it relates to an apparatus for controlling the concentration of an etchant, a wiring board manufactured by using this apparatus, and a manufacturing method of such wiring board.

### BACKGROUND OF THE INVENTION

Taper processing technology of a metal thin film of aluminum or mainly composed of aluminum by a conventional wet etching method is disclosed, for example, in Japanese Laid-open Patent No. 6-122982.

A taper processing technology of a metal thin film of aluminum or mainly composed of aluminum by a conventional wet etching method using an etchant is described. FIG. 6 is a sectional view showing each step of mechanism of a conventional taper processing technology. In FIG. 6(A), a glass substrate 1 is used as substrate, and an aluminum metal thin film 2 is deposited on the entire surface of the glass substrate 1 in a film thickness of about 300 nm. The depositing method is sputtering method or electron beam vapor deposition method. By an ordinary photolithographic method, a desired resist pattern 3 is formed on the aluminum metal thin film 2. At this time, the post-baking temperature of the photo resist has a great effect on the etching shape, and post-baking is done, for example, at about 135.

Consequently, in FIG. 6(B), an etchant is prepared by mixing phosphoric acid with concentration of 85 wt. %, a nitric acid with concentration of 61 wt. %, acetic acid, and water, by 16 parts, 4 parts, 4 parts, and 1 part by volume, respectively. The aluminum metal film is patterned at 40° C. by using this etchant. An etching apparatus of batch immersion type or spray type is used. The aluminum metal thin film in a film thickness of about 300 nm is etched uniformly in the longitudinal direction and lateral direction, which is the feature of wet etching, in the initial phase of etching. As the etching proceeds, the nitric acid as etching substance contained in the etchant oozes into the interface of the resist and the aluminum metal thin film, and this nitric acid swells the resist, and hence the etching in the lateral direction is advanced more than in the longitudinal direction as indicated by arrows 8 and 9. This etching time is, for example, 90 seconds, and adding an over-etching time of 30%, it is about 2 minutes.

Further, as shown in FIG. 6(C), the metal thin film is etched. Finally, by removing the photo resist, a pattern 4 of aluminum metal thin film having a taper angle of about 60° is formed as shown in FIG. 6(D).

In such taper processing technology of metal thin film of aluminum or mainly composed of aluminum, along with the progress of etching, the etching substance contained in the etchant produces difference in the concentration changes. For example, the concentration of the nitric acid as etching substance changes in the process of etching. By this concentration change of the etching substance, the taper angle of the etched metal thin film is changed. This concentration change is greater in the spray type etching apparatus, which is in the mainstream of wet etching in the recent trend of larger size of glass substrate, than in the conventional batch immersion type etching apparatus. In this spray type etching apparatus, due to concentration change of the nitric acid which has a correlation with the taper angle of the etchant, the taper angle is changed significantly as compared with the initial time of supplying the etchant. In addition, the concentration of the acetic acid contained in the etchant is also changed, and due to this concentration change of acetic acid, the etching speed is extremely changed as compared with the initial time of supplying the etchant.

### SUMMARY OF THE INVENTION

An etching apparatus for processing a metal thin film of the invention includes:

(a) an etchant containing an etching substance,

(b) etching means for making contact between the etchant and the metal thin film, and

(c) control means for controlling the concentration of the etching substance contained in the etchant.

The control means includes:

(1) concentration measuring means for measuring the concentration of an etching substance,

(2) calculating means for calculating an addition amount of the etching substance on the basis of the concentration measured by the concentration measuring means, and

(3) adding means for supplying the addition amount calculated by the calculating means into the etchant.

Preferably, the concentration measuring means measures automatically the concentration of the etching substance at specified time intervals, the calculating means calculates automatically the addition amount, and the adding means supplies automatically the addition amount to the etchant.

An etching method for processing a metal thin film into a metal wiring having a taper shape section of a desired angle of the invention includes:

(a) a step of placing a resist having a desired pattern shape on the surface of the metal thin film,

(b) a step of causing an etchant to contact with the metal thin film having the desired pattern shape,

(c) a step of maintaining an etching substance contained in the etchant at a desired concentration, and

(d) a step of etching the metal thin film in a region excluding the portion covered with the resist by the etchant.

The step of maintaining the etching substance at desired concentration includes:

(1) a step of measuring the concentration of the etching substance contained in the etchant,

(2) a step of calculating an addition amount of the etching substance on the basis of the measured concentration, and

(3) a step of supplying the addition amount into the etchant.

Preferably, the concentration of the etching substance is measured automatically at specified time intervals at the step (1), the addition amount is calculated automatically at the step (2), and the addition amount is automatically supplied to the etchant at the step (3).

A wiring board of the invention is manufactured by using the above etching apparatus or etching method.

In this constitution, the composition of the etchant can be always kept constant. That is, it is possible to control the concentration of the etching substance contained in the etchant. By controlling the concentration of the etching substance contained in the etchant, the metal thin film is processed into a taper sectional shape of a desired angle, and the etching speed is controlled and the etching speed is stabilized. The wiring board manufactured in this constitution has a wiring performance with a stable shape. In particular, the gate wiring and source wiring of liquid crystal device manufactured in this constitution provides an extremely stable display performance.

### BRIEF DESCRIPTION OF THE DRAWING

FIG. 1 is a block diagram of a control system for controlling etchant concentration in accordance with an exemplary embodiment of the present invention.

FIG. 2 is a process chart of etching method in an embodiment of the invention.

FIG. 3(A) is a graph showing concentration changes of nitric acid before and after change of etchant in an exemplary embodiment of the present invention and in the prior art, FIG. 3(B) is a graph showing concentration changes of acetic acid, FIG. 3(C) is a graph showing concentration changes of phosphoric acid, and FIG. 3(D) is a graph showing changes of etching end time.

FIG. 4 is a correlation diagram of concentration of nitric acid contained in an etchant mixing phosphoric acid, nitric acid, acetic acid, and water, and taper angle of etched aluminum metal thin film.

FIG. 5(A), FIG. 5(B), and FIG. 5(C) are side views illustrating the taper shape of the aluminum metal thin film, FIG. 5(A) illustrates the taper shape of aluminum metal thin film at nitric acid concentration of 5 wt. %, FIG. 5(B) illustrates the taper shape of aluminum metal thin film at nitric acid concentration of 9 wt. %, and FIG. 5(C) illustrates the taper shape of aluminum metal thin film at nitric acid concentration of 11 wt. %.

FIGS. 6(A)-(D) are sectional views illustrating exemplary taper processing technology in the prior art, FIG. 6(A) illustrates Al metal thin film formed on a glass substrate, with a photo resist formed thereon, FIG. 6(B) illustrates the midst of etching, FIG. 6(C) illustrates the end of etching, and FIG. 6(D) illustrates the sectional shape of metal thin film after removing the resist.

### REFERENCE NUMERALS

1 Glass substrate

2 Metal thin film

3 Photo resist

11 Etching apparatus

12 Concentration measuring means

13 Calculating means

14 Liquid adding means

15 Etching means

16 Tank

21 Substrate

22 Metal thin film

23 Resist

### DETAILED DESCRIPTION OF THE INVENTION

An etching apparatus for processing a metal thin film includes:

(a) an etchant containing etching substances,

(b) etching means for making contact between the etchant and the metal thin film, and

(c) control means for controlling the concentration of the etching substances contained in the etchant.

The control means includes:

(1) concentration measuring means for measuring the concentration of the etching substances,

(2) calculating means for calculating an addition amount of the etching substances on the basis of the concentration measured by the concentration measuring means, and

(3) adding means for supplying the addition amount calculated by the calculating means into the etchant.

Preferably, the concentration measuring means measures automatically the concentration of the etching substances at specified time intervals, the calculating means calculates automatically the addition amount, and the adding means supplies automatically the addition amount to the etchant.

Preferably, the control means converts the measured concentration into an electric signal, transmits to a computer storing a set concentration, converts the difference between the concentration and the set concentration into an electric signal, and calculates the addition amount.

Preferably, a resist of a first pattern shape is put on the surface of the metal thin film, a region excluding the portion covered with the resist is etched by the etchant, and the metal thin film in the portion covered with the resist is processed into a taper sectional shape of a desired angle.

Preferably, the metal thin film is at least one of (i) aluminum and (ii) an alloy mainly composed of aluminum.

Preferably, the etching substances contain at least one substance selected from the group consisting of nitric acid, acetic acid and phosphoric acid.

Preferably, the etching substances contain nitric acid and acetic acid, the concentration measuring means measures the concentration of at least one etching substance of the nitric acid and the acetic acid, the calculating means calculates an addition amount of at least the one etching substance, and the adding means supplies the addition amount to the etchant.

Preferably, the wiring board manufactured by using the above etching apparatus or etching method has the gate wiring and source wiring used in an array substrate of a liquid crystal display device.

An exemplary embodiment of the invention is described below.

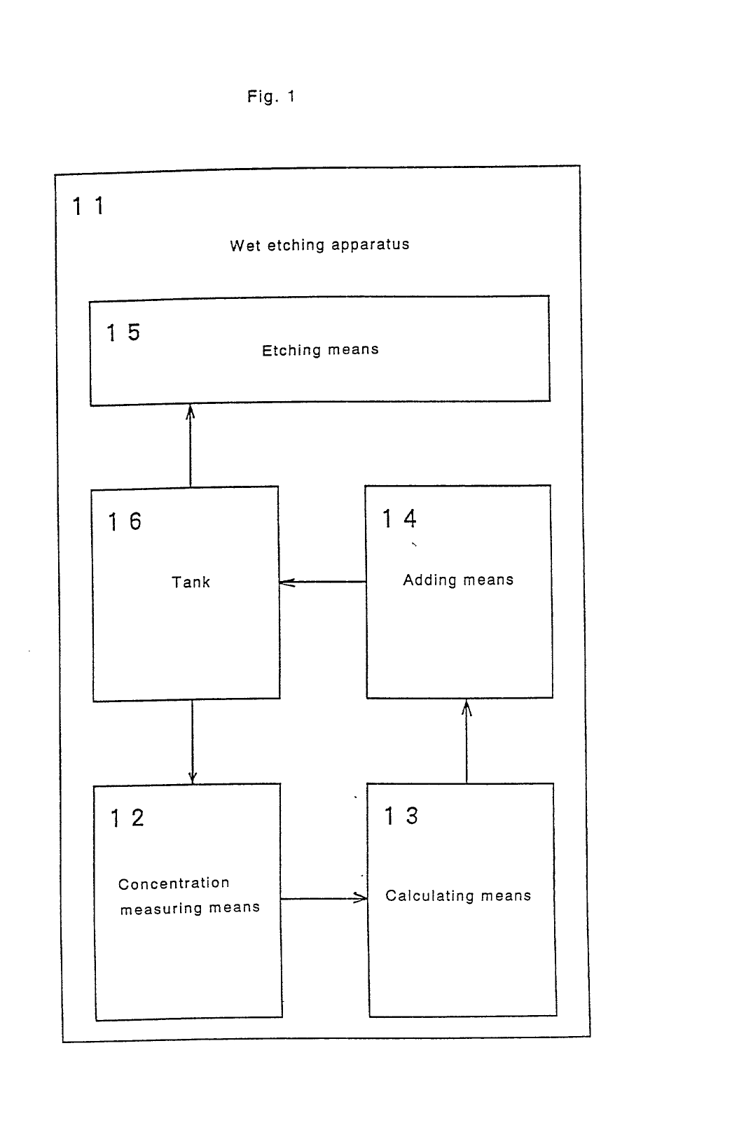

FIG. 1 is a block diagram of an etching apparatus in accordance with an exemplary embodiment of the invention. In FIG. 1, an etching apparatus 11 comprises etching means 15 for etching a metal thin film, an ion chromatograph 12 as means for measuring automatically the concentration of the etchant, calculating means 13 for calculating the addition amount of the etchant, adding means 14 for adding the etching substances, and a tank 16 containing the etchant.

The etching means 15 etches the metal thin film of aluminum or mainly composed of aluminum on the glass substrate. The ion chromatograph 12 measures the concentration of the etchant. The calculating means 13 converts the result of measurement of the ion chromatograph 12 into an electric signal, transmits it to a computer, converts the difference of the measured concentration and a set concentration range into an electric signal, and calculates the addition amount of the desired etching substances. The adding means 14 adds automatically the desired etching substances to the tank 16 according to the electric signal sent from the calculating means 13.

In thus constituted etching apparatus of the exemplary embodiment of the present invention, the operation is described below.

The spray type etching apparatus 11 is a wet etching apparatus for finely processing a metal thin film of aluminum or mainly composed of aluminum. The etchant is a mixed liquid of phosphoric acid, nitric acid, acetic acid, and water, and is a solution mixing 85 wt. % phosphoric acid, 61 wt. % nitric acid, 99.8 wt. % acetic acid, and water, by 16 parts, 4 parts, 4 parts, and 1 part by volume, respectively. Using this etchant, the metal thin film of aluminum or mainly composed of aluminum was patterned at 40° C. by taper etching processing technology.

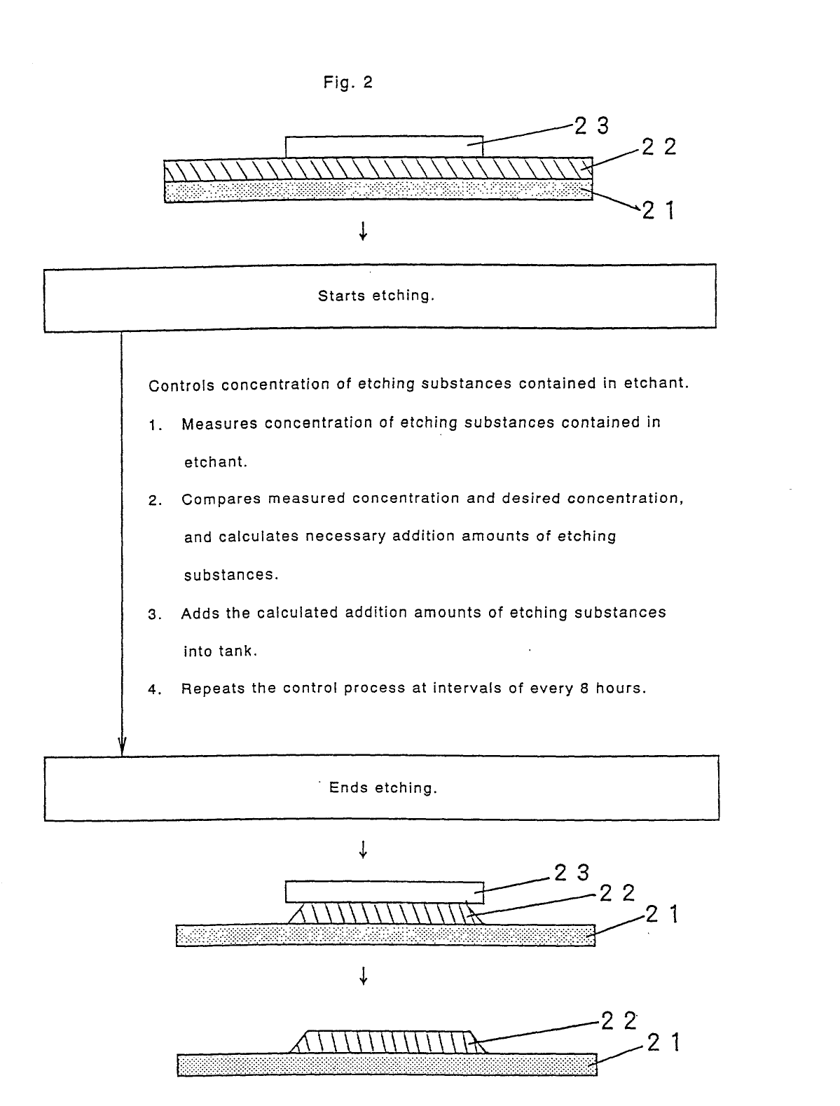

The etching method is shown in FIG. 2. In FIG. 2, a metal thin film 22 is placed on a glass substrate 21, and a photo resist 23 is placed on the metal thin film 22 in a specified shape. Etching is started by using the specified etching apparatus 11. As etching progresses, the ion chromatograph 12 as concentration measuring means takes in the etchant in-line from the tank 16, and measures concentration of phosphoric acid, nitric acid, and acetic acid at measuring intervals that can be set as desired. In this embodiment, the measuring intervals were set at every 8 hours.

The calculating means 13 receives (in signal form) the result of measurement from the ion chromatograph 12 calculates the difference of the measured concentration and the set concentration range, and calculates the addition amount of the desired etching substances. The adding means 14 supplies and replenishes the necessary amounts of 70 wt. % nitric acid and 99.8 wt. % acetic acid into the tank 16 according to the calculation result from the calculating means 13.

In this way, the etching operation of the metal thin film was continued while controlling the concentration of the etching substances contained in the etchant.

Meanwhile, when etching the metal thin film of aluminum or aluminum alloy, the etchant is desired to be a mixed liquid containing water and etching substances such as about 30 to about 80 wt. % of phosphoric acid, about 5 to about 30 wt. % of nitric acid, and about 0 to about 30 wt. % of acetic acid. If the concentration of the etching substances is out of the specified range, the etching capacity is slightly inferior. Preferably, nitric acid should be contained by about 8 to about 30 wt. %. If the nitric acid concentration is more than about 30 wt. %, the taper angle of the etched metal thin film is smaller, and if the nitric acid concentration is less than about 5 wt. %, the etching performance is inferior. If the acetic acid concentration is more than about 30 wt. %, the etching speed is slow.

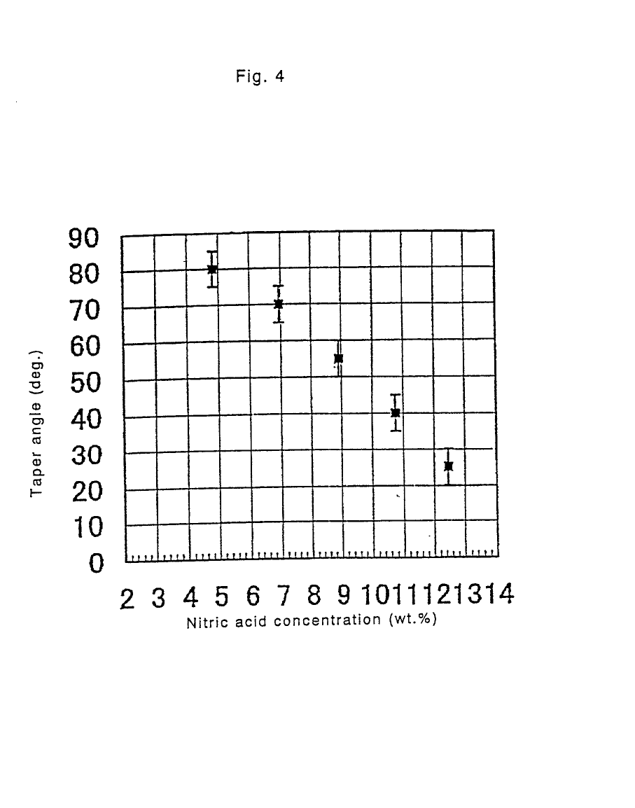

FIG. 4 shows the relation between the concentration of nitric acid contained in the etchant, and the taper angle of the etched aluminum metal thin film. The etchant is a mixed liquid of water and etching substances such as phosphoric acid, nitric acid and acetic acid. In FIG. 4, the taper angle of the etched metal thin film depends on the nitric acid concentration. This is because the adhesion of the resist depends on the nitric acid concentration. Therefore, by the control of nitric acid concentration, the taper shape of the section of the metal thin film can be controlled in a range from about 20? to about 80?.

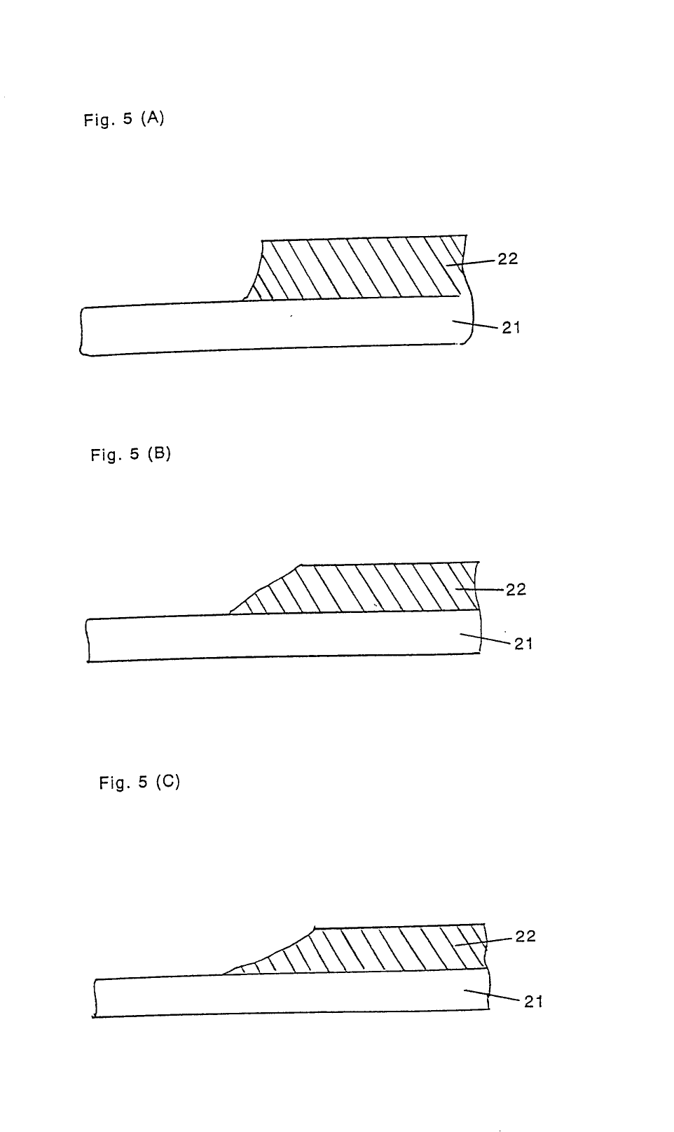

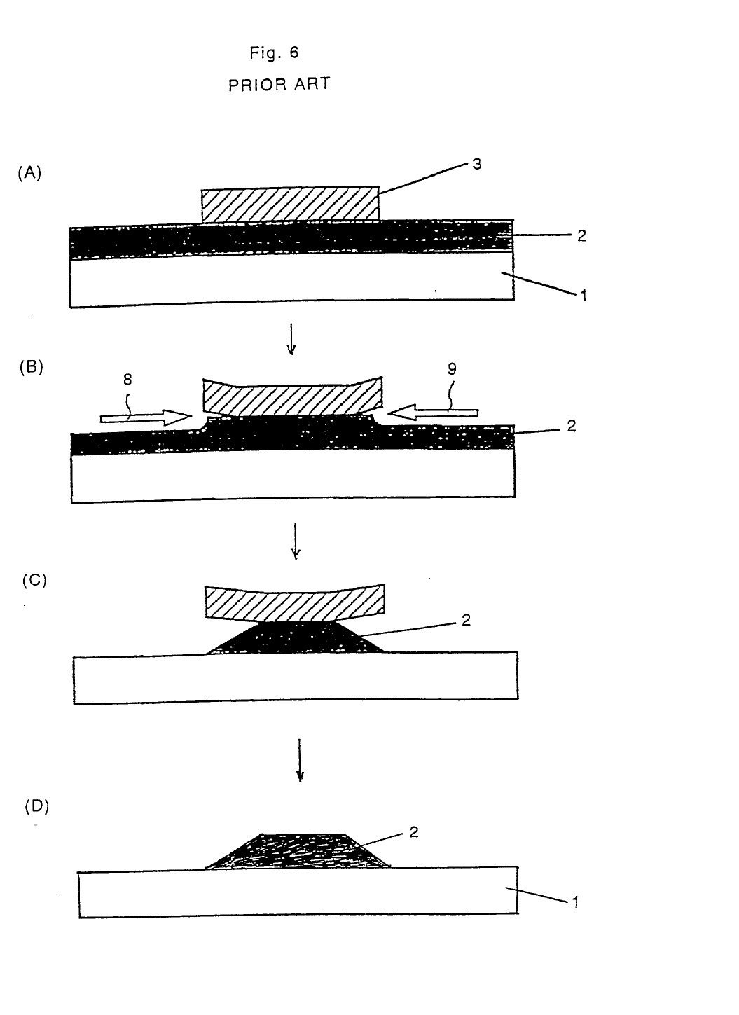

FIG. 5(A), FIG. 5(B), and FIG. 5(C) are sectional views illustrating the taper shape of the aluminum metal thin film etched by using etchants at various concentrations of nitric acid. FIG. 5(A) is at nitric acid concentration of 5 wt. %, FIG. 5(B) at nitric acid concentration of 9 wt. %, and FIG. 5(C) at nitric acid concentration of 11 wt. %. As the nitric acid concentration becomes higher, the taper angle of the aluminum thin film 22 placed on the substrate 21 becomes smaller. That is, by controlling the concentration of nitric acid contained in the etchant, the taper shape of the aluminum thin film can be controlled.

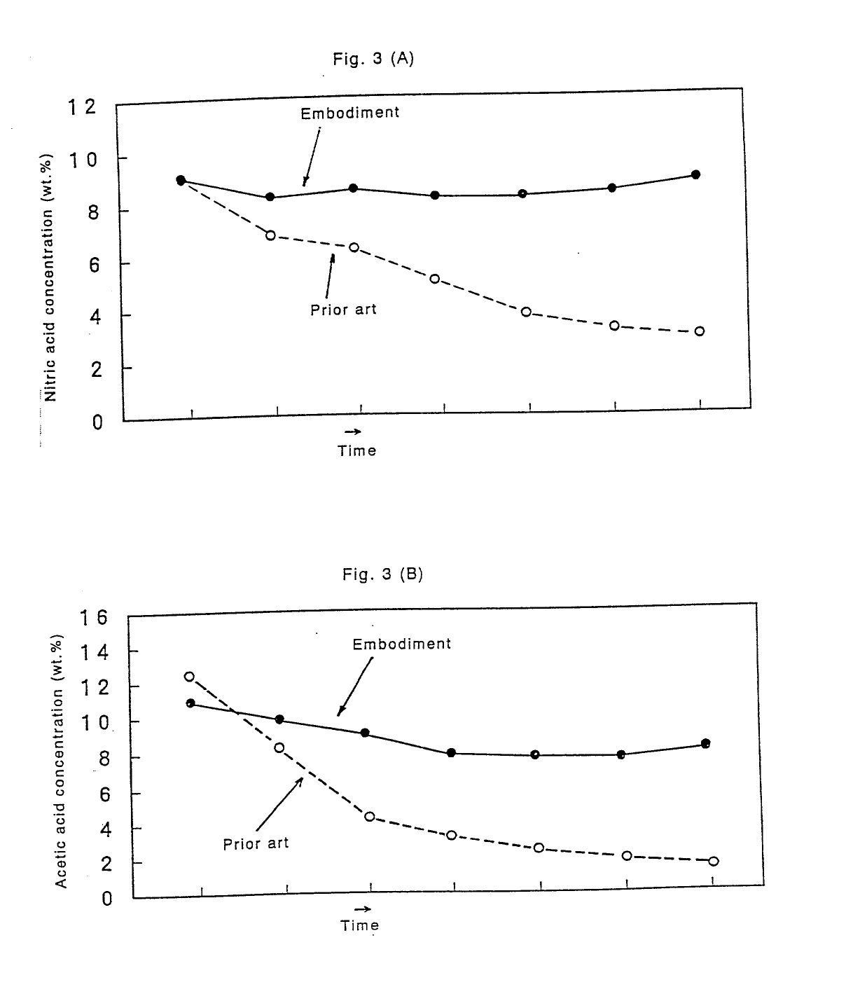

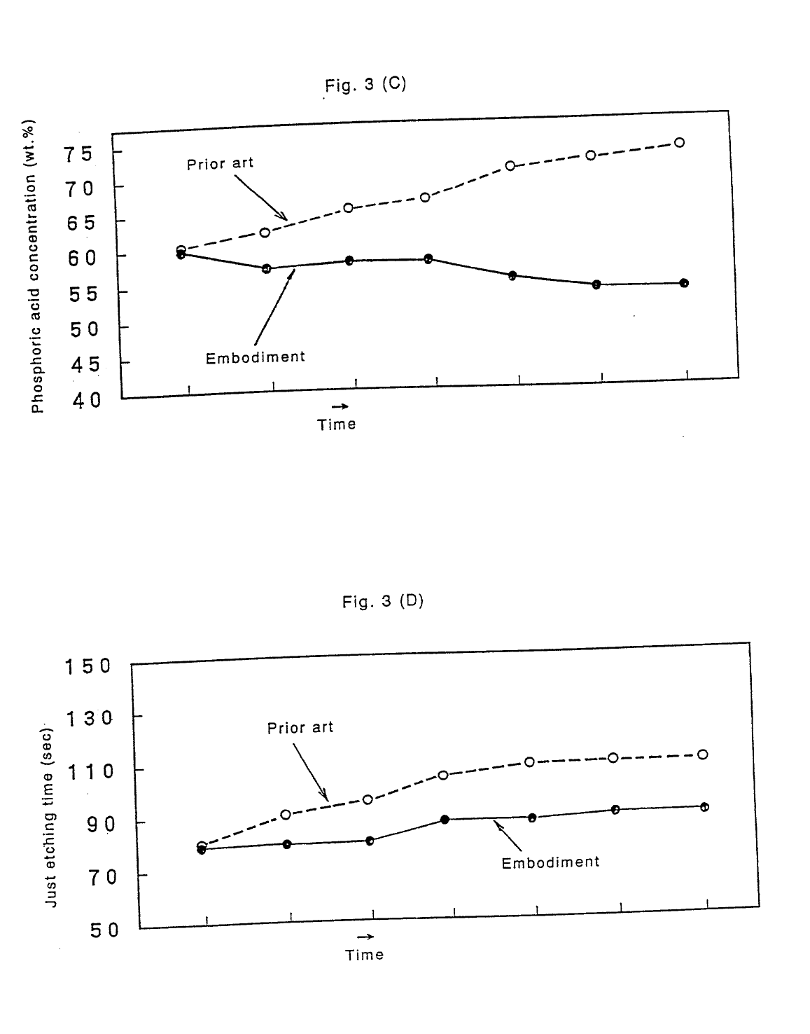

FIG. 3(A) to FIG. 3(D) are graphs showing changes before and after change of etchant in an exemplary embodiment of the present invention and etchant in the prior art, that is, FIG. 3(A) shows concentration changes of nitric acid, FIG. 3(B) shows concentration changes of acetic acid, FIG. 3(C) shows concentration changes of phosphoric acid, and FIG. 3(D) shows changes of just etching time.

In FIG. 3(A), the nitric acid concentration in the etching tank in this exemplary embodiment does not change with passage of time, and is kept always at a constant concentration. By contrast, the nitric acid concentration in the prior art is extremely reduced with passage of time.

In FIG. 3(B), the acetic acid concentration in the etching tank in this exemplary embodiment does not change with passage of time, and is kept always at a constant concentration. By contrast, the acetic acid concentration in the prior art is extremely reduced with passage of time.

In FIG. 3(C), the phosphoric acid concentration in the etching tank in this exemplary embodiment does not change with passage of time, and is kept always at a constant concentration. By contrast, the phosphoric acid concentration in the prior art is extremely reduced with passage of time.

In FIG. 3(D), etching time in the exemplary embodiment changes less than etching time in the prior art.

That is, as shown from FIG. 3(A) to FIG. 3(D), according to the method of the exemplary embodiment, concentration changes of components in the etching tank are small, and a constant concentration is always maintained. The sectional shape of the etched metal thin film changes depending on the concentration of the etchant in the tank. In this exemplary embodiment, therefore, since the concentration of the etchant in the tank is kept at a constant concentration, the sectional shape of the etched metal thin film always maintains a specific shape, not changing with the lapse of time. Moreover, in the exemplary embodiment, it is possible to control the concentration of each component contained in the etchant. By controlling the concentration of each component, the metal thin film can be etched into a sectional shape having a desired taper angle. Moreover, as clear from the results of experiment in FIG. 3(D), it is possible to control and stabilize the etching speed.

Thus, according to the exemplary embodiment, the wet etching apparatus 11 for finely processing the metal thin film of aluminum or mainly composed of aluminum comprises the ion chromatograph 12 for measuring automatically the concentration of etching substances contained in the etchant, the calculating means 13 for converting the result of measurement into an electric signal, transmitting it to the computer, comparing with the concentration measuring range, converting the difference into an electric signal, and calculating the addition amount of the etchant from the required ion concentration, and adding means 14 for supplying the necessary etching substances into the tank 16.

In this constitution, during the etching process, depending on concentration changes of the etching substances in the etchant in the tank 16, necessary amounts of etching substances such as nitric acid and acetic acid are added, and the concentration of the etching substances contained in the etchant during etching can be controlled. By concentration control of the etching substances, the etching shape and etching speed can be controlled and stabilized. In particular, by controlling the concentration of nitric acid contained in the etchant, the taper angle of the metal thin film can be controlled to a desired angle. Further, by controlling the concentration of acetic acid contained in the etchant, the etching speed of the metal thin film can be controlled to a desired speed. Still more, if the concentration of the etching substances exceeds the desired concentration range, the nitric acid and acetic acid can be supplied into the tank, at arbitrary addition intervals, by addition amounts that can be set as desired.

In the exemplary embodiment, the ion chromatograph is used as the concentration measuring means 12. It is also possible to use the concentration measuring means depending on the absorption photometry. The adding means 14 is a mechanism for adding nitric acid and acetic acid. It is also possible to add independently etching substances such as phosphoric acid, nitric acid and acetic acid. It is also possible to add a mixed solution of etching substances such as nitric acid and acetic acid. In such cases, the same effects as above are obtained.

As described herein, the composition of the etchant can be stabilized, and the concentration of the etchant can be controlled, and therefore the taper shape of metal thin film and etching speed can be controlled, and the taper shape of metal thin film and etching speed can be stabilized.

A wiring board having wiring manufactured in accordance with the abovecan be used as the gate wiring and source wiring used in the array substrate of liquid crystal display device. In this case, particularly excellent effects are obtained, and a liquid crystal display having a stable display performance is obtained.

1. An etching apparatus for processing a metal thin film, comprising:
(a) an etchant containing an etching substance,
(b) etching means for making contact between said etchant and said metal thin film, and
(c) control means for controlling a concentration of said etching substance contained in said etchant, said control means comprising:
(1) concentration measuring means for measuring the concentration of said etching substance,
(2) calculating means for calculating an addition amount of said etching substances on the basis of said concentration measured by said concentration measuring means, and
(3) adding means for supplying said addition amount calculated by said calculating means into said etchant.

2. An etching apparatus of claim 1,
wherein said concentration measuring means measures the concentration of said etching substance at specified time intervals, said calculating means calculates said addition amount, and said adding means supplies said addition amount to said etchant.

3. An etching apparatus of claim 1,
wherein said control means calculates said addition amount based on a difference between said measured concentration and said set concentration.

4. An etching apparatus of claim 1,
wherein a resist of a desired pattern shape is put on a surface of said metal thin film, a region excluding a portion of said metal thin film covered with said resist is etched by said etchant, and said metal thin film in the portion covered with said resist is processed into a taper sectional shape of a desired angle.

5. An etching apparatus of claim 1,
wherein said metal thin film is at least one of (i) aluminum and (ii) an alloy which includes aluminum.

6. An etching apparatus of claim 1,
wherein said etching substance includes at least nitric acid and phosphoric acid.

7. An etching apparatus of claim 1,
wherein said etching substance includes nitric acid and acetic acid, said concentration measuring means measures the concentration of at least one etching substance of said nitric acid and said acetic acid, said calculating means calculates an addition amount of at least said one etching substance, and said adding means supplies said addition amount to said etchant.

8. An etching apparatus of claim 1,
wherein said metal thin film is at least one of (i) aluminum and (ii) an alloy which includes aluminum, said etching substance includes nitric acid and acetic acid, said concentration measuring means measures each concentration of said nitric acid and said acetic acid, said calculating means calculates said addition amount of nitric acid and acetic acid, and said adding means supplies said addition amount of nitric acid and acetic acid to etchant.

9. An etching apparatus of claim 1,
wherein said metal thin film is at least one of (i) aluminum and (ii) an alloy mainly composed of aluminum, said etching substance contain phosphoric acid, nitric acid and acetic acid, and said etchant includes 30 to 80 wt. % of said phosphoric acid, 5 to 30 wt. % of said nitric acid, 0 to 30 wt. % of said acetic acid, and water.

10. An etching apparatus of claim 1,
wherein said concentration measuring means uses ion chromatography.

11. An etching apparatus of claim 1,
wherein said control means maintains said concentration of said etching substance is maintained at a desired concentration, and as said desired concentration is maintained, said metal thin film is processed into a taper sectional shape of a desired angle.

12. An etching apparatus of claim 1,
wherein said etchant is contained in a tank.

13. An etching apparatus of claim 1,
wherein said etching means causes said etchant to contact with said metal thin film in spray form.

14. An etching apparatus of claim 1,
wherein said etchant is contained in a tank, and said addition amount of said etching substance is supplied into said tank.

15. An etching apparatus of claim 1,
wherein said concentration measuring means samples part of said etchant, and measures the concentration of said sampled part of said etchant.

16. An etching apparatus of claim 1, wherein said etching apparatus is for manufacturing a wiring board.

17. An etching apparatus of claim 1, wherein said etching apparatus is for manufacturing a gate wiring and a source wiring used in an array substrate of a liquid crystal display device.

18. An etching method for processing a metal thin film into a metal wiring having a taper shape section of a desired angle, comprising the steps of:
(a) placing a resist having a desired pattern shape on a surface of said metal thin film,
(b) causing an etchant to contact with said metal thin film having the desired pattern shape,
(c) maintaining an etching substance contained in said etchant at a desired concentration, said step of maintaining the etching substances at desired concentration comprising:
(1) measuring the concentration of said etching substance contained in said etchant,
(2) calculating an addition amount of said etching substance on the basis of said measured concentration, and
(3) supplying said addition amount into said etchant, and
(d) etching said metal thin film in a region excluding the portion covered with said resist by said etchant.

19. An etching method of claim 18,
wherein the concentration of said etching substance is measured at specified time intervals at step (1), said addition amount is calculated at step (2), and said addition amount is supplied to said etchant at step (3).

20. An etching method of claim 18,
wherein at said step of maintaining the etching substance at a desired concentration, said addition amount is calculated based on a difference between said measured concentration and said set concentration.

21. An etching method of claim 18,
wherein said metal thin film is at least one of (i) aluminum and (ii) an alloy which includes aluminum.

22. An etching method of claim 18,
wherein said etching substance includes at least nitric acid and phosphoric acid.

23. An etching method of claim 18,
wherein by said step of causing said etchant containing etching substance maintained at desired concentration to contact with said metal thin film covered with said resist, said metal thin film is processed into a taper sectional shape of a desired angle, and said wiring having said desired pattern shape is formed.

24. An etching method of claim 18,
wherein said etchant contacts with said metal thin film in spray form.

25. An etching method of claim 18,
wherein said etchant is contained in a tank, and said addition amount of said etching substance is supplied into said tank.

26. An etching method of claim 18,
wherein part of said etchant is sampled, and the concentration of the sampled etchant is measured.

27. An etching method of claim 18,
wherein said metal thin film is at least one of (i) aluminum and (ii) an alloy which includes aluminum, said etching substance includes phosphoric acid, nitric acid and acetic acid, and said etchant includes 30 to 80 wt. % of said phosphoric acid, 5 to 30 wt. % of said nitric acid, 0 to 30 wt. % of said acetic acid, and water.

28. An etching method of claim 18, said method for manufacturing a wiring board.

29. An etching method of claim 18, said method for manufacturing a gate wiring and a source wiring used in an array substrate of a liquid crystal display device.

30. A wiring board manufactured by using the etching apparatus of claim 1.

31. A wiring board manufactured by using the etching apparatus in claim 1, said wiring board having a gate wiring and a source wiring used in an array substrate of a liquid crystal display device.

32. A wiring board manufactured by using the etching apparatus of claim 18.

33. A wiring board manufactured by using the etching apparatus of claim 18, having a gate wiring and a source wiring used in an array substrate of a liquid crystal display device.

34. A wiring board comprising:
(a) a substrate, and
(b) a metal wiring disposed on said substrate, having a desired pattern with a taper shape section of a desired angle,
wherein said metal wiring is processed into said taper shape section of a desired angle using an etching method c which comprises the steps of:
(1) placing a resist having a desired pattern shape on the surface of said metal thin film,
(2) causing an etchant to contact with said metal thin film having the desired pattern shape,
(3) maintaining an etching substance contained in said etchant at a desired concentration, said step of maintaining the etching substance at desired concentration comprising:
(1) measuring the concentration of said etching substance contained in said etchant,
(2) calculating an addition amount of said etching substance on the basis of said measured concentration, and
(3) supplying said addition amount into said etchant, and
(4) etching said metal thin film in a region excluding the portion covered with said resist by said etchant.

35. A wiring board of claim 34,
wherein the concentration of said etching substance is measured at specified time intervals at step 1), said addition amount is calculated automatically at step 2), and said addition amount is automatically supplied to said etchant at step 3).

36. A wiring board of claim 34,
wherein at said step of maintaining the etching substance at a desired concentration, said addition amount is calculated based on a difference between said measured concentration and said set concentration.

37. A wiring board of claim 34,
wherein said metal thin film is at least one of (i) aluminum and (ii) an alloy which includes aluminum.

38. A wiring board of claim 34,
wherein said metal wiring includes at least one of gate wiring and source wiring used in an array substance of a liquid crystal display device.

39. A wiring board of claim 34,
wherein said etching substance includes at least nitric acid and phosphoric acid.

40. A wiring board of claim 34,
wherein by said step of causing said etchant containing etching substance maintained at desired concentration to contact with said metal thin film covered with said resist, said metal thin film is processed into a taper sectional shape of a desired angle, and said wiring having said desired pattern shape is formed.
